(19) United States
(12) Patent Application Publication
(10) Pub. No.: US 2023/0155058 A1
(43) Pub. Date: May 18, 2023

(54) Optoelectronic Component

(71) Applicant: ams-OSRAM International GmbH, Regensburg (DE)

(72) Inventor: Laura Kreiner, Regensburg (DE)

(21) Appl. No.: 17/995,832

(22) PCT Filed: Apr. 1, 2021
(86) PCT No.: PCT/EP2021/058575

§ 371 Date: Oct. 7, 2022

(30) Foreign Application Priority Data
Apr. 8, 2020 (DE) 10 2020 204 539.9

(51) Int. Cl. H01L 33/10; H01L 33/50

(52) U.S. Cl. CPC H01L 33/10; H01L 33/502

(57) ABSTRACT

In an embodiment an optoelectronic component includes a semiconductor body having an active region configured to generate primary electromagnetic radiation and an exit surface, a first and a second dielectric mirror each located on the exit surface; and a conversion element between the second dielectric mirror and the exit surface, wherein the component is configured to emit radiation having a first peak at a first wavelength and a second peak at a second wavelength, wherein the second peak results at least in part from a conversion of radiation generated in the optoelectronic component by the conversion element, wherein each spectral width of the first and second peaks is at most 50 nm, wherein the first dielectric mirror is transmissive to radiation of the first wavelength incident at angles of incidence in a predetermined first angular range and is reflective to radiation of the first wavelength incident at angles of incidence in a predetermined second angular range, and wherein the second dielectric mirror is transmissive to radiation of the second wavelength incident at angles of incidence in the first angular range and reflective to radiation of the second wavelength incident at angles of incidence in the second angular range.

This patent application is a national phase filing under section 371 of PCT/EP2021/058575, filed Apr. 1, 2021, which claims the priority of German patent application 102020204539.9, filed Apr. 8, 2020, each of which is incorporated herein by reference in its entirety.

### TECHNICAL FIELD

The disclosure refers to an optoelectronic component.

### SUMMARY

Embodiments provide an optoelectronic component that emits radiation efficiently.

According to at least one embodiment, the optoelectronic component comprises a semiconductor body having an active region for generating primary electromagnetic radiation. Furthermore, the semiconductor body has an exit surface.

For example, the semiconductor body is based on a III-V compound semiconductor material. The semiconductor material is, for example, a nitride compound semiconductor material, such as AlnIn1-n-mGamN, or a phosphide compound semiconductor material, such as AlnIn1-n-mGamP, or an arsenide compound semiconductor material, such as AlnIn1-n-mGamAs or AlnIn1-n-mGamAsP, wherein, in each case, 0≤n≤1, 0≤m≤1, and m+n≤1. The semiconductor body may have dopants as well as additional components. For simplicity, however, only the essential constituents of the crystal lattice of the semiconductor body, i.e. Al, As, Ga, In, N or P, are indicated, even if these may be partially replaced and/or supplemented by small amounts of additional substances. Preferably, the semiconductor body is based on AlInGaN.

The active region of the semiconductor body includes in particular at least one pn junction and/or at least one quantum well structure in the form of a single quantum well, SQW for short, or in the form of a multi-quantum well structure, MQW for short. For example, the active region generates primary electromagnetic radiation in the blue or green or red spectral range or in the UV range or in the IR range during intended operation.

The primary radiation generated during operation is in particular incoherent radiation. The component is in particular a light-emitting diode (LED) or a light-emitting diode chip (LED chip).

The exit surface forms a top surface of the semiconductor body and is formed from the material of the semiconductor body. In the intended operation of the component, a major part, i.e. at least 50% or at least 75% or at least 90%, of the primary radiation emitted by the semiconductor body exits the semiconductor body via the exit surface. In particular, more radiation exits the semiconductor body via the exit surface than enters during operation. For example, at least twice as much or at least five times as much or at least ten times as much radiation exits as enters. On a rear side of the semiconductor body opposite to the exit surface, a mirror layer is preferably arranged, which is for example reflective for the entire visible spectrum and/or the primary radiation. The mirror layer may comprise a metallic layer and/or a dielectric layer.

The optoelectronic component is, for example, a semiconductor chip or a so-called chip-size package component. Both in the case of a semiconductor chip and in the case of a chip-size package component, its lateral dimensions, measured parallel to a main extension plane of the semiconductor body, essentially correspond to the lateral dimensions of the semiconductor body. In particular, the lateral dimensions of the component are then at most 20% or at most 10% or at most 5% larger than those of the semiconductor body. Lateral surfaces of the component extending transversely to the main extension plane may have traces of a separation process resulting from a separation from a wafer composite. In a chip-size package component, the side surfaces are made of a potting material, such as epoxy.

The component may be free of the growth substrate on which the semiconductor body is grown. In particular, the component is a thin film chip or a component with a thin film chip.

The component can be pixelated in such a way that the semiconductor body comprises several individually and independently controllable emission areas (pixels). During operation of the emission areas, primary radiation is emitted via a partial area of the exit surface assigned to each such emission area. For example, the semiconductor body is divided into at least four or at least 10 or at least 50 emission areas.

According to at least one embodiment, the optoelectronic component comprises a first dielectric mirror and a second dielectric mirror. Both dielectric mirrors are arranged on the same side of the semiconductor body, namely on the exit surface. The dielectric mirrors are, for example, each periodic structures, i.e., Bragg mirrors, or non-periodic structures. The first dielectric mirror and the second dielectric mirror are arranged one above the other with respect to the exit surface. That is, the first dielectric mirror is arranged between the exit surface and the second dielectric mirror or vice versa.

The dielectric mirrors preferably each comprise several, for example at least two or at least four or at least ten or at least 50 or at least 100, dielectric layers stacked above each other with respect to the exit surface. The dielectric layers of each dielectric mirror are, for example, alternately high-refractive and low-refractive. Here, the refractive index of a high-refractive layer differs from that of a low-refractive layer by at least 0.1 or at least 0.3 or at least 0.5 or at least 1.0. For example, the low-refractive layers have a refractive index of at most 2. For example, the high-refractive layers have a refractive index of at least 2.3. The values for the refractive index are given here for the primary radiation.

For example, in at least one dielectric mirror, the dielectric layers alternate in such a way that one low-refractive layer lies between every two high-refractive layers and vice versa. In a periodic structure, the thicknesses of all dielectric layers are the same within the manufacturing tolerance. In a non-periodic structure, the thicknesses of the dielectric layers vary.

The low refractive layers comprise or consist of, for example, at least one of the following materials: SiO2, SiN, SiON, MgF2. The high refractive layers comprise or consist of, for example, at least one of the following materials: Nb2O5, TiO2, ZrO2, HfO2, Al2O3, Ta2O5, ZnO. The thicknesses of the dielectric layers are, for example, each between 10 nm and 300 nm, inclusive.

According to at least one embodiment, the optoelectronic component comprises a conversion element between the second dielectric mirror and the exit surface. The conversion element is configured to convert radiation generated in the component. In particular, the conversion element converts the primary radiation to a longer wavelength spectral range during operation of the component. The conversion element may comprise or consist of one or more conversion materials.

In top view, the dielectric mirrors and the conversion element cover most of the exit surface and the semiconductor body, respectively, for example by at least 80% or completely.

According to at least one embodiment, a radiation emitted by the component in operation has a first peak at a first wavelength and a second peak at a second wavelength. The first wavelength is the wavelength at which the first peak has its maximum. The second wavelength is the wavelength at which the second peak has its maximum. For example, the first wavelength is in the blue spectral range. For example, the first wavelength is between 440 nm and 490 nm, inclusive. The second peak is shifted with respect to the first peak by, for example, at least 50 nm or at least 100 nm, for example red shifted. For example, the second wavelength is in the green and/or yellow and/or red spectral range. For example, the second wavelength is between 490 nm and 590 nm, inclusive, or between 490 nm and 700 nm, inclusive.

Peaks are defined here and in the following as significant elevations in the intensity distribution of the radiation generated or emitted by the component, plotted over the wavelength. The peaks are preferably clearly separated from each other. For example, the intensity distribution of the radiation in the region between the first and the second wavelength drops to values of less than 30% or less than 10% or less than 1% of the value at the first or second wavelength.

According to at least one embodiment, the second peak results at least partially, in particular largely or completely, from the conversion of radiation generated in the component by the conversion element. That is, the emission spectrum of the conversion element exhibits a peak at the second wavelength. The emission spectrum of a conversion element is the spectrum emitted by the conversion element due to excitation by electromagnetic radiation, such as primary radiation. In other words, the emission spectrum is the fluorescence spectrum of the conversion element.

The first peak can be a peak in the intensity distribution of the primary radiation. Alternatively, the first peak may also result at least partially or largely or completely from the conversion of radiation generated in the component by the conversion element or by another conversion element. If the first peak results from the emission from a conversion element, this conversion element is preferably arranged between the first dielectric mirror and the exit surface.

According to at least one embodiment, the spectral width of the first and the second peak is at most 50 nm or at most 25 nm or at most 10 nm or at most 5 nm, respectively. The spectral width is understood to be, for example, the full width half maximum (FWHM). Alternatively, the spectral width is understood to be the width at which the intensity in the intensity distribution has dropped to 1/e from the maximum value in the peak.

According to at least one embodiment, the first dielectric mirror is transmissive to radiation of the first wavelength incident on the first dielectric mirror at angles of incidence in a predetermined first angular range and reflective to radiation of the first wavelength incident on the first dielectric mirror at angles of incidence in a predetermined second angular range. The first angular range and the second angular range preferably do not overlap. For radiation of the second wavelength, for example, the first dielectric mirror is transmissive at all angles of incidence or reflective at all angles of incidence.

According to at least one embodiment, the second dielectric mirror is transmissive to radiation of the second wavelength incident on the second dielectric mirror at angles of incidence in the first angular range and reflective to radiation of the second wavelength incident on the second dielectric mirror at angles of incidence in the second angular range. For radiation of the first wavelength, for example, the second dielectric mirror is transmissive at all angles of incidence or only in the first angular range.

Angles of incidence are measured here as angles to a normal to the respective dielectric mirror. A normal to a dielectric mirror is understood to be a normal to the main extension plane of the dielectric mirror.

By “transmissive” it is understood here and in the following that an element transmits or passes at least 75%, preferably at least 90%, particularly preferably at least 99% of a radiation. By “reflective” it is understood that an element reflects more than 75%, preferably at least 90%, particularly preferably at least 99% of a radiation.

The expressions “predetermined first angular range” and “predetermined second angular range” refer to the fact that, when designing a dielectric mirror, the angular range in which it is transmissive and the angular range in which it is reflective can be precisely and almost arbitrarily set by selecting the materials of the dielectric layers and the thickness of the dielectric layers. In this respect, the angular ranges for transmission and reflection can be predetermined.

In at least one embodiment, the optoelectronic component comprises a semiconductor body having an active region for generating primary electromagnetic radiation and an exit surface, as well as a first and a second dielectric mirror each on the exit surface, respectively, and further comprises a conversion element between the second dielectric mirror and the exit surface. A radiation emitted by the component in operation has a first peak at a first wavelength and a second peak at a second wavelength. The second peak results at least in part from conversion of radiation generated in the component by the conversion element. The spectral width of each of the first peak and the second peak is at most 50 nm. The first dielectric mirror is transmissive to radiation of the first wavelength incident on the first dielectric mirror at angles of incidence in a predetermined first angular range and is reflective to radiation of the first wavelength incident on the first dielectric mirror at angles of incidence in a predetermined second angular range. The second dielectric mirror is transmissive to radiation of the second wavelength incident on the second dielectric mirror with angles of incidence in the first angular range and reflective to radiation of the second wavelength incident on the second dielectric mirror with angles of incidence in the second angular range.

Embodiments are particularly based on the recognition that in many applications of optoelectronic components, only radiation in a small angular range can be used, resulting in the loss of much radiation in typical Lambertian radiation sources. Etendue-limited applications can also increase the luminance in the application if the radiation profile can be improved. Many wave-optic elements, such as dielectric mirrors, cannot be used to improve directionality, or can only be used with limitations, because they do not combine well with a very broadband spectrum, for example in white LEDs.

In the embodiments, use is made of the idea of providing an optoelectronic component that emits a radiation spectrum with an intensity distribution that has at least two narrowband and spaced-apart peaks. For each narrowband peak, it is possible to provide a dielectric mirror optimized for exactly this radiation. This provides a component that emits radiation efficiently over a wide range of wavelengths in a well-defined, preferably narrow, first angular range.

The component disclosed herein is suitable, for example, as a radiation source in a headlight, in particular in a headlight of a vehicle, or in a projector or as a radiation source for the backlighting of a display, for example a smartphone display or a display for a vehicle interior.

According to at least one embodiment, the first angular range comprises all angles of incidence between 0° inclusive and a inclusive, measured with respect to a normal to the respective dielectric mirror. The first angular range thus forms a cone with the normal as the axis of rotation and an aperture angle of 2·α. For example, a has a value of at most 75° or at most 60° or at most 45° or at most 30° or at most 20° or at most 10°. Alternatively or additionally, the value for α is, for example, at least 5° or at least 10°.

According to at least one embodiment, the second angular range comprises all angles of incidence of at least β measured with respect to the normal to the respective dielectric mirror, where β≥α. Preferably, β is at least 1° or at least 5° or at least 10° greater than α. Alternatively or additionally, β is at most 10° or at most 5° greater than α. Preferably, the second angular range includes all angles of incidence between and including β and 90°.

According to at least one embodiment, the first dielectric mirror has a transmittance of at least 75% or at least 90% or at least 99% for radiation of the first wavelength incident with angles of incidence in the first angular range and a reflectance of at least 75% or at least 90% or at least 99% for radiation of the first wavelength incident with angles of incidence in the second angular range. The specified values of the transmittance and the reflectance for radiation of the first wavelength apply particularly preferably to all angles of incidence in the respective angular range.

According to at least one embodiment, the second dielectric mirror has a transmittance of at least 75% or at least 90% or at least 99% for radiation of the second wavelength incident with angles of incidence in the first angular range and a reflectance of at least 75% or at least 90% or at least 99% for radiation of the second wavelength incident with angles of incidence in the second angular range. The specified values of the transmittance and the reflectance for radiation of the second wavelength apply particularly preferably to all angles of incidence in the respective angular range.

According to at least one embodiment, the exit surface has a structuring. For example, the exit surface is roughened. An average roughness of the exit surface is then, for example, at least 500 nm or at least 1000 nm. Due to the structuring of the exit surface, a redistribution of the radiation reflected by the dielectric mirrors can be achieved, so that, when it next impinges on a dielectric mirror, it impinges on the respective dielectric mirror, if applicable, with an angle of incidence in the first angular range.

According to at least one embodiment, a planarization layer is applied to the exit surface, which is planar and/or smooth on a side facing away from the semiconductor body. In particular, the planarization layer is applied directly to the exit surface. In particular, the planarization layer is then arranged between the dielectric mirrors and the exit surface. The planarization layer preferably comprises a transparent material which is transparent for the radiation generated in the component, in particular the primary radiation and the converted radiation, such as silicon dioxide (SiO2). The planarization layer simplifies and improves the deposition of the dielectric mirrors.

According to at least one embodiment, the conversion element is arranged between the first dielectric mirror and the exit surface. In this case, the first dielectric mirror is preferably transmissive to radiation of the second wavelength, particularly preferably at all angles of incidence or in the first angular range.

According to at least one embodiment, the first dielectric mirror is arranged between the conversion element and the exit surface. In this case, the first dielectric mirror may be reflective or transmissive to radiation of the second wavelength, for example at all angles of incidence.

According to at least one embodiment, the radiation emitted by the component in operation has a third peak at a third wavelength. The third wavelength is shifted with respect to the first and/or second wavelength, for example by at least 50 nm or at least 100 nm, for example red shifted.

According to at least one embodiment, the spectral width of the third peak is at most 50 nm or at most 25 nm or at most 10 nm or at most 5 nm. The definition for the spectral width is the same as above. For example, the third peak or the third wavelength is in the orange and/or red spectral range. For example, the third wavelength is between 590 nm and 700 nm, inclusive.

For wavelengths in the range between the peaks, the intensity of the radiation emitted by the component is preferably much lower, for example at most 30% or at most 10% or at most 1%, than at the maximum of the peaks.

According to at least one embodiment, the component comprises a third dielectric mirror on the exit surface. With respect to the composition of several dielectric layers, the third dielectric mirror may be constructed in the same manner as the first and second dielectric mirrors. Therefore, all features disclosed in connection with the first and second dielectric mirrors are also disclosed for the third dielectric mirror.

According to at least one embodiment, the third dielectric mirror is transmissive to radiation of the third wavelength incident on the third dielectric mirror at angles of incidence in the first angular range and reflective to radiation of the third wavelength incident on the third dielectric mirror at angles of incidence in the second angular range. For the first and/or second wavelengths, the third dielectric mirror may be transmissive at any angle of incidence.

According to at least one embodiment, the third peak results at least in part, in particular largely or completely, from the conversion of radiation generated in the component, in particular the primary radiation, by the conversion element.

In other words, the emission spectrum of the conversion element comprises a peak at the third wavelength in addition to the second peak and possibly in addition to the first peak. In this case, the conversion element comprises, for example, at least two different conversion materials, with different emission spectra. The emission spectrum with the third peak occurs, for example, by conversion of the primary radiation and/or other radiation generated in the component.

The component can also emit radiation with more than three peaks during operation. In this case, there is an associated dielectric mirror for each peak, for example.

According to at least one embodiment, the component comprises a second conversion element for converting radiation generated in the component, for example, the primary radiation.

According to at least one embodiment, the third peak results at least in part, in particular largely or completely, from the conversion of radiation generated in the component, for example the primary radiation, by the second conversion element.

In other words, the second conversion element has an emission spectrum that has a peak at the third wavelength. The conversion element, which is also referred to as the first conversion element in the following, and the second conversion element are in particular spatially separated from each other. For example, the conversion element and the second conversion element are arranged one above the other with respect to the exit surface.

For example, the conversion element and the second conversion element have different conversion materials.

According to at least one embodiment, one of the dielectric mirrors is arranged between the conversion element and the second conversion element. Alternatively, it is also conceivable that no dielectric mirror is arranged between the conversion element and the second conversion element. For example, the conversion element and the second conversion element are then directly adjoining each other.

According to at least one embodiment, the conversion element and/or the second conversion element comprise quantum dots and/or nanoplatelets. The quantum dots and/or nanoplatelets then form the conversion material or a conversion material in the respective conversion element. The quantum dots and/or nanoplatelets preferably comprise or consist of semiconductor material, such as CdSe, CdTe, CdS, InP, CUInS, Si, Ge, C, PbS, InGaAs, GaInP. For protection, these materials may be surrounded by a cladding, for example of ZnS.

Nanoplatelets consist of several superimposed semiconductor layers with a total thickness of a few atomic layers, for example at most 50 nm or at most 10 nm or at most 5 nm. Quantum dots and nanoplatelets can be used to achieve particularly narrow-band emission spectra. Alternatively, however, other conversion materials, for example oxide or nitride or oxynitride conversion materials, are also conceivable.

One advantage of nanoplatelets is that one can define the exact number of the atomic layers by the growth conditions. Thus, all nanoplatelets have the same thicknesses. Since the thickness is the smallest dimension of the platelets, it also defines the wavelength. This means that very narrow-band emission can then also be achieved in the ensemble, because inhomogeneous broadening of the emission can be excluded by the defined manufacturing process.

The conversion materials of the conversion elements may be embedded in a matrix material, for example of silicone or epoxy. Alternatively, the conversion elements can be made of conversion material, for example sintered or pressed conversion material.

According to at least one embodiment, the component emits white light during operation. In particular, a mixture of the narrowband first peak and the narrowband second peak, possibly together with the narrowband third peak, forms white light.

Alternatively, however, it is also conceivable that the radiation emitted by the component during operation is radiation in the red and/or infrared spectral range. For example, the first peak is in the red or infrared spectral range and the second peak is in the infrared spectral range. The component is then suitable, for example, as a radiation source in spectrometer applications or sensor applications.

To fabricate the component, the dielectric mirrors and possibly the conversion element(s) can first be deposited on a glass wafer. This is then subsequently applied to the semiconductor body. The finished component may have the glass platelet. The dielectric mirrors and the conversion element or conversion elements are then preferably arranged between the glass wafer and the semiconductor body.

### BRIEF DESCRIPTION OF THE DRAWINGS

Further advantages and advantageous embodiments and further developments of the optoelectronic component result from the following exemplary embodiment shown in connection with the figures. Identical, similar or similar-acting elements are provided with the same reference signs in the figures. The figures and the proportions of the elements shown in the figures are not to be regarded as to scale. Rather, individual elements, in particular layer thicknesses, may be shown exaggeratedly large for better representability and/or for better understanding.

FIGS. 1, 3-5, 7-10 and 12 show exemplary embodiments of the optoelectronic component, each in cross-sectional view;

FIGS. 2, 6 and 11 show intensity distributions of the radiation generated by the components; and

FIG. 13 shows an example of the angular selectivity of dielectric mirrors.

### DETAILED DESCRIPTION OF ILLUSTRATIVE EMBODIMENTS

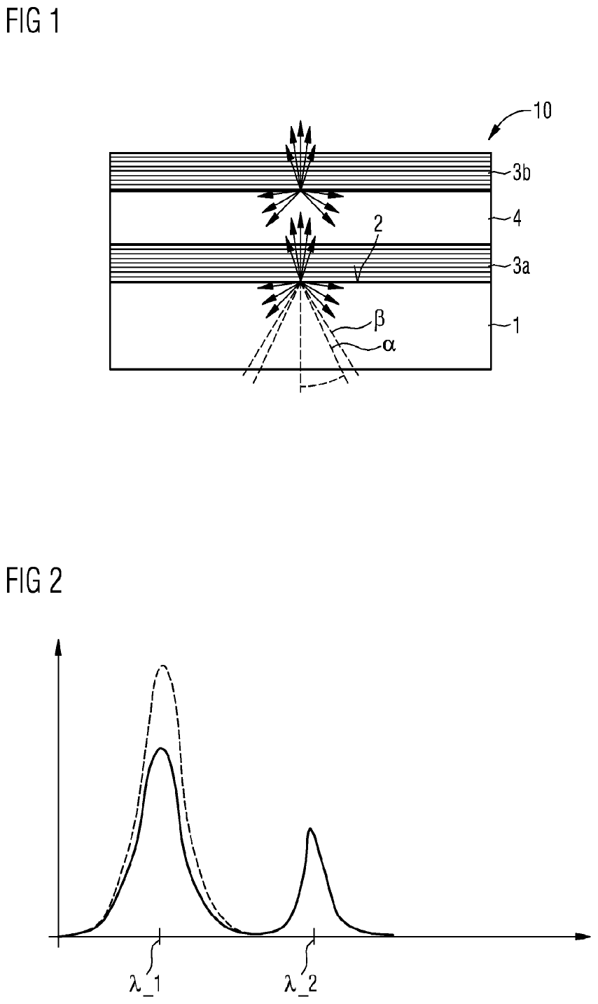

FIG. 1 shows a first exemplary embodiment of the optoelectronic component 10 and FIG. 2 shows the corresponding intensity distribution of the radiation emitted by the component 10. The component 10 comprises a semiconductor body 1, for example based on AlInGaN, with an active region (not shown). In the active region, a primary radiation is generated in the intended operation. In the present case, the primary radiation is, for example, radiation in the blue spectral range. The primary radiation has a narrow-band first peak with a spectral width of at most 50 nm. The maximum of the peak lies at a first wavelength λ_1 (see FIG. 2).

A first dielectric mirror 3a is arranged on an exit surface 2 of the semiconductor body 1. A large part of the primary radiation generated by the semiconductor body 1 emerges from the semiconductor body 1 via the exit surface 2 during the intended operation of the component 10. The first dielectric mirror 3a is configured to be transmissive to radiation of the first wavelength λ_1 incident with angles of incidence in a first angular range between 0° and a inclusive, and to be reflective to radiation of the first wavelength λ_1 incident with angles of incidence in a second angular range outside the first angular range (from β to 90°). For example, the value for a is 30°. The value for β is 35°, for example.

A conversion element 4 is arranged on the side of the dielectric mirror 3a facing away from the semiconductor body 1. The conversion element 4 is configured to convert the primary radiation, wherein the emission spectrum of the conversion element 4 has a second peak at a second wavelength λ_2 (see FIG. 2). The second peak is also narrow-band with a spectral width of, for example, at most 50 nm. The second peak, respectively the second wavelength 2, lies, for example, in the green to yellow spectral range. An emission spectrum with a narrow-band peak is realized, for example, by the conversion element having 4 quantum dots or nanoplatelets of semiconductor material.

A second dielectric mirror 3b is arranged on the side of the conversion element 4 facing away from the semiconductor body 1. The second dielectric mirror 3b is configured to transmit radiation of the second wavelength λ_2 incident with angles of incidence in the first angular range and to reflect radiation of the second wavelength λ_2 incident with angles of incidence in the second angular range. For radiation of the first wavelength λ_1, the second dielectric mirror 3b is preferably transmissive, especially preferably at angles of incidence between 0° and α.

Because the component 10 generates and emits radiation with narrow-band peaks, dielectric mirrors can be used that are particularly efficient and angle-selective for radiation of the respective peak. Overall, the entire component efficiently emits directional radiation. The emitted radiation is, for example, white light.

In the intensity distribution shown in FIG. 2, the wavelength is shown on the x-axis and the intensity is shown on the y-axis. The dashed curve represents the primary radiation generated in the semiconductor body 1. In the radiation finally emitted by the component 10 (solid curve), the intensity of the primary radiation is reduced due to the conversion.

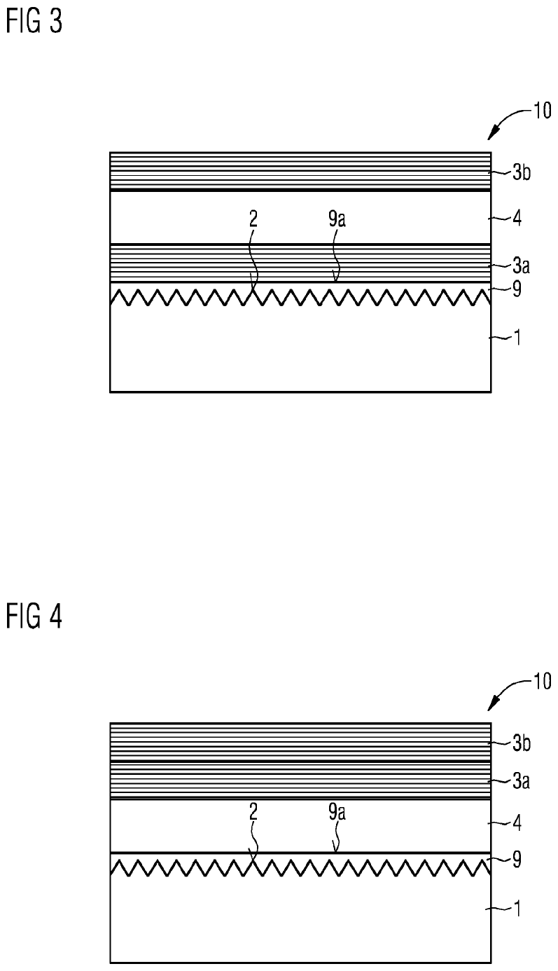

FIG. 3 shows a second exemplary embodiment of the optoelectronic component 10. Here, the exit surface 2 of the semiconductor body 1 is structured/roughened. Radiation reflected back from the dielectric mirrors 3a, 3b can be redistributed by the structuring and, if applicable, impinge on the dielectric mirrors 3a, 3b in the first angular range at the next impingement.

A planarization layer 9, for example of SiO2, is applied here to the structured exit surface 2, which is planar and smooth on a side 9a facing away from the semiconductor body 1. The average roughness of the side 9a is less than 1 nm, for example.

FIG. 4 shows a third exemplary embodiment of the optoelectronic component 10. Here, both dielectric mirrors 3a, 3b are applied to the side of the conversion element 4 facing away from the semiconductor body 1.

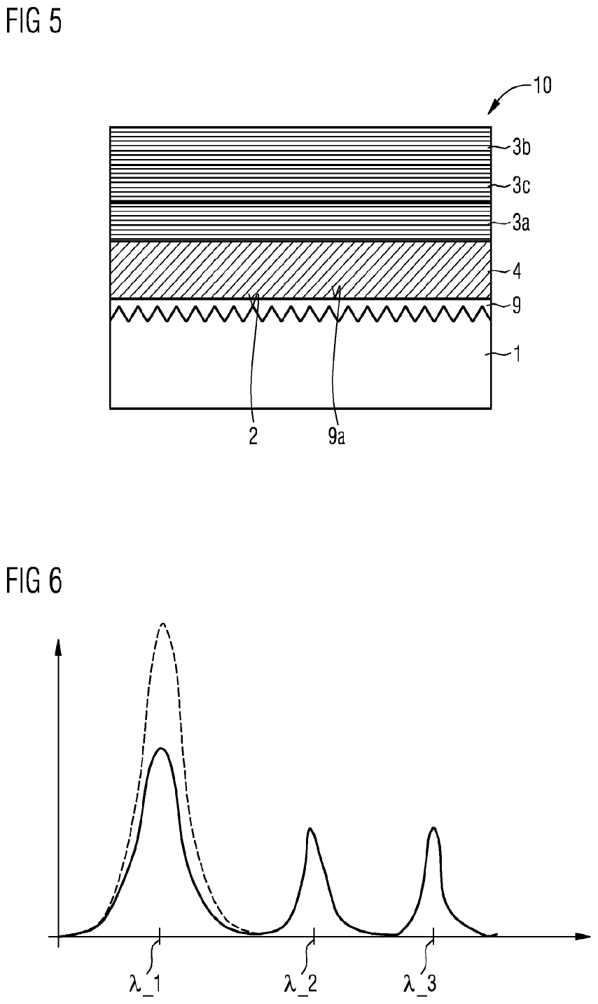

FIG. 5 shows a fourth exemplary embodiment of the optoelectronic component 10 and FIG. 6 the corresponding intensity distribution of the radiation emitted by the component 10 (solid curve). Here, primary radiation is again generated by the semiconductor body 1 (dashed curve in FIG. 6), which has a first peak at a first wavelength λ_1 in the blue spectral range wherein the first peak is narrow-band. The conversion element 4 has an emission spectrum that, in addition to the second peak at the second wavelength λ_2 in the green spectral range, also has a narrow-band third peak at a third wavelength λ_3. For example, the third wavelength λ_3 is in the red spectral range (see FIG. 6). To realize the emission spectrum of the conversion element 4, it comprises, for example, two different conversion materials, each of which may be formed by quantum dots or nanoplatelets.

For the third peak, a third dielectric mirror 3c is provided in the component 10m, said third dielectric mirror 3c transmits radiation of the third wavelength 3 incident with angles of incidence in the first angular range and reflects radiation of the third wavelength λ_3 incident with angles of incidence in the second angular range. The three dielectric mirrors 3a, 3b, 3c are located downstream of the conversion element 4.

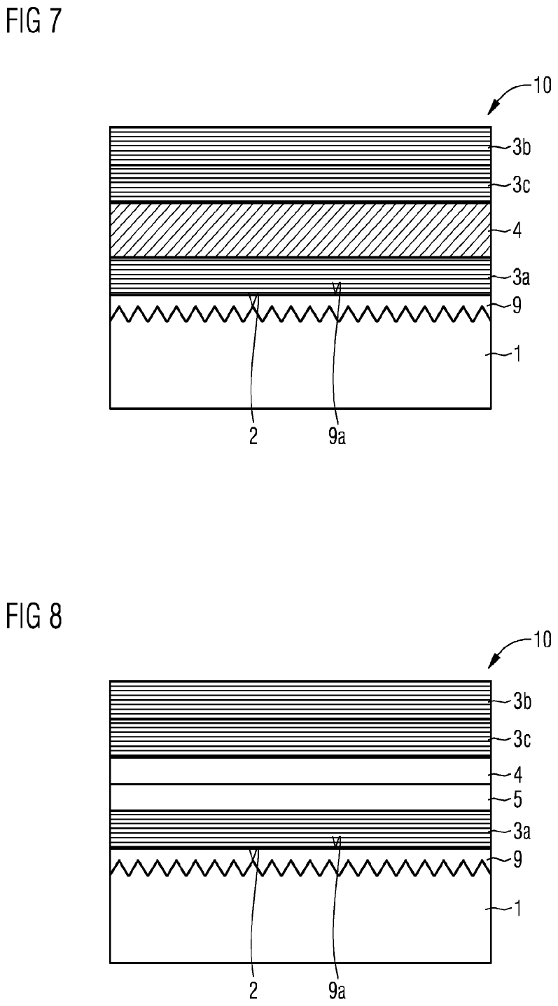

In FIG. 7, a fifth exemplary embodiment of the component 10 is shown in which, unlike in the fourth embodiment, the first dielectric mirror 3a is arranged between the conversion element 4 and the exit surface 2.

FIG. 8 shows a sixth exemplary embodiment of the component 10. This one differs from the component 10 of FIG. 7 in that a second conversion element 5 is used here in addition to the conversion element 4. The first conversion element 4 has an emission spectrum with the second peak at the second wavelength λ_2. The second conversion element 5 has an emission spectrum with the third peak at the third wavelength λ_3. The first conversion element 4 and the second conversion element 5 are spatially separated from each other, in this case arranged directly above each other.

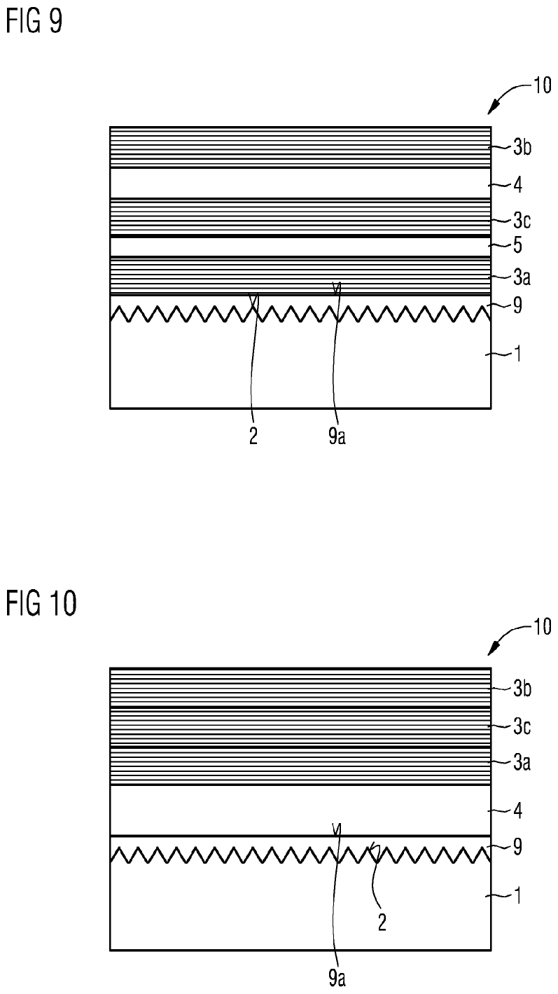

FIG. 9 shows a seventh exemplary embodiment of the component 10, which differs from that of FIG. 8 in that here the third dielectric mirror 3c is arranged between the first conversion element 4 and the second conversion element 5.

FIG. 10 shows an eighth exemplary embodiment of the component 10 in which the semiconductor body 1 generates primary radiation in the ultraviolet spectral range rather than in the blue spectral range as in the previous exemplary embodiments. The conversion element 4 located downstream of the semiconductor body 4 exhibits an emission spectrum with three narrow-band peaks at the first wavelength λ_1, the second wavelength λ_2, and the third wavelength λ_3. For example, the conversion element 4 converts at least 90% or all of the primary radiation. For example, the first wavelength λ_1 is again in the blue spectral range, the second wavelength λ_2 is in the green spectral range, and the third wavelength λ_3 is in the red spectral range. The radiation emitted by the component 10 is, for example, white light. In FIG. 10, the dielectric mirrors 3a, 3b, 3c associated with the respective wavelengths are arranged downstream of the conversion element 4 in the direction away from the semiconductor body 1.

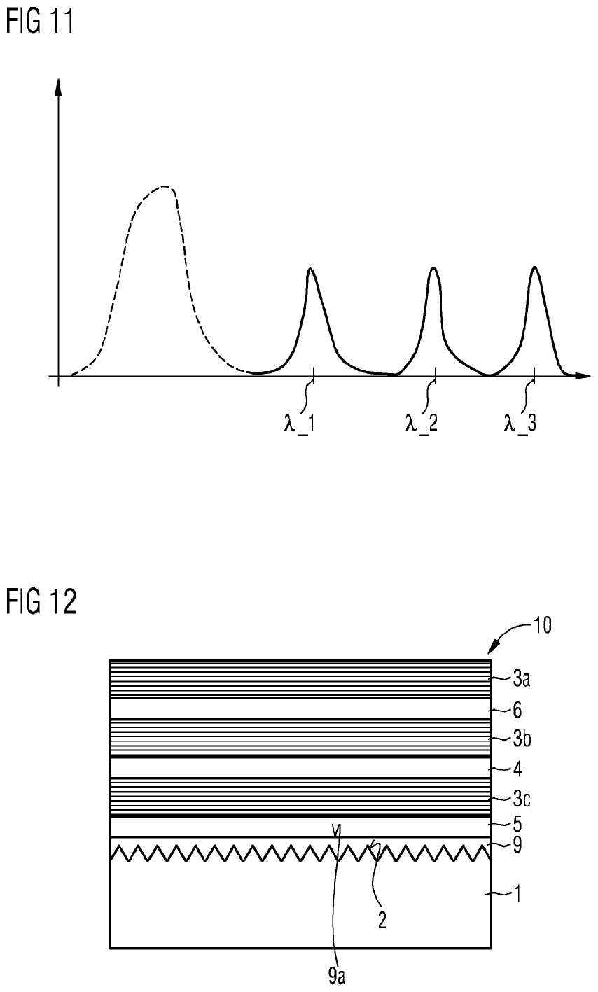

The spectrum emitted by the component 10 of FIG. 10 in operation is shown in FIG. 11 (solid curve). The dashed peak of the primary radiation generated by the semiconductor body is not or hardly present in the emitted spectrum.

FIG. 12 shows a ninth exemplary embodiment of the optoelectronic component 10. Unlike in FIG. 10, three conversion elements 4, 5, 6 are provided here. The first conversion element 4 has an emission spectrum comprising the second peak. The second conversion element 5 has an emission spectrum comprising the third peak, and a third conversion element 6 has an emission spectrum comprising the first peak. The third conversion element 6 may also have, for example, quantum dots or nanoplatelets.

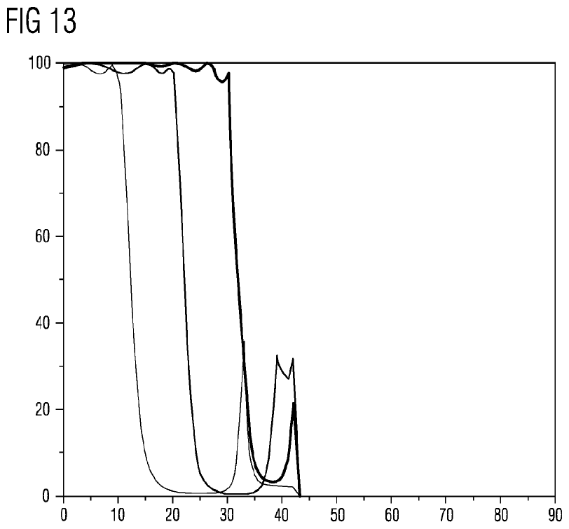

FIG. 13 shows an exemplary embodiment of the angular selectivity of three different dielectric mirrors. On the y-axis, the transmittance is shown in percent. On the x-axis the angle of incidence is shown in degrees. One of the dielectric mirrors is nearly 100% transmissive up to incidence angles of 10°. A second dielectric mirror is nearly 100% transmissive up to angles of incidence of up to 20°. A third dielectric mirror is almost 100% transmissive up to angles of incidence of up to 30°.

The invention described herein is not limited by the description in conjunction with the exemplary embodiments. Rather, the invention comprises any new feature as well as any combination of features, particularly including any combination of features in the patent claims, even if said feature or said combination per se is not explicitly stated in the patent claims or exemplary embodiments.

### LIST OF REFERENCE SIGNS

1 semiconductor body
2 exit surface
3a first dielectric mirror
3b second dielectric mirror
3c third dielectric mirror
4 (first) conversion element
5 second conversion element
6 third conversion element
9 planarization layer
9a side of the planarization layer
10 optoelectronic component
λ_1 first wavelength
λ_2 second wavelength
λ_3 third wavelength
α angle
β angle

1-12. (canceled)

13. An optoelectronic component comprising:
a semiconductor body having an active region configured to generate primary electromagnetic radiation and an exit surface;
a first and a second dielectric mirror each located on the exit surface; and
a conversion element between the second dielectric mirror and the exit surface,
wherein the optoelectronic component is configured to emit a radiation having a first peak at a first wavelength and a second peak at a second wavelength,
wherein the second peak results at least in part from a conversion of radiation generated in the optoelectronic component by the conversion element,
wherein each spectral width of the first and second peaks is at most 50 nm,
wherein the first dielectric mirror is transmissive to radiation of the first wavelength incident at angles of incidence in a predetermined first angular range and is reflective to radiation of the first wavelength incident at angles of incidence in a predetermined second angular range, and
wherein the second dielectric mirror is transmissive to radiation of the second wavelength incident at angles of incidence in the first angular range and reflective to radiation of the second wavelength incident at angles of incidence in the second angular range.

14. The optoelectronic component according to claim 13,
wherein the first angular range comprises all angles of incidence between 0° and α, inclusive, measured with respect to a normal to a respective dielectric mirror,
wherein the second angular range comprises all angles of incidence of at least β measured with respect to the normal to the respective dielectric mirror, and
wherein β≥α.

15. The optoelectronic component according to claim 13,
wherein the first dielectric mirror has a transmittance of at least 75% for radiation of the first wavelength incident with angles of incidence in the first angular range and a reflectance of at least 75% for radiation of the first wavelength incident with angles of incidence in the second angular range, and
wherein the second dielectric mirror has a transmittance of at least 75% for radiation of the second wavelength incident at angles of incidence in the first angular range and a reflectance of at least 75% for radiation of the second wavelength incident at angles of incidence in the second angular range.

16. The optoelectronic component according to claim 13,
wherein the exit surface has a structuring,
wherein a planarization layer is located at the exit surface, the planarization layer being planar on a side facing away from the semiconductor body.

17. The optoelectronic component according to claim 13, wherein the conversion element is arranged between the first dielectric mirror and the exit surface.

18. The optoelectronic component according to claim 13, wherein the first dielectric mirror is arranged between the conversion element and the exit surface.

19. The optoelectronic component according to claim 13,
wherein the optoelectronic component is configured to emit the radiation having a third peak at a third wavelength,
wherein the spectral width of the third peak is at most 50 nm,
wherein the optoelectronic component has a third dielectric mirror on the exit surface, and
wherein the third dielectric mirror is transmissive to radiation of the third wavelength incident at angles of incidence in the first angular range and reflective to radiation of the third wavelength incident at angles of incidence in the second angular range.

20. The optoelectronic component according to claim 19, wherein the third peak results at least in part from the conversion of radiation generated in the optoelectronic component by the conversion element.

21. The optoelectronic component according to claim 19,
wherein the optoelectronic component comprises a second conversion element configured to convert radiation generated in the optoelectronic component,
wherein the third peak results from the conversion of radiation generated in the optoelectronic component by the second conversion element.

22. The optoelectronic component according to claim 21, wherein one of the dielectric mirrors is arranged between the conversion element and the second conversion element.

23. The optoelectronic component according to claim 13, wherein the conversion element comprises quantum dots or nanoplatelets.

24. The optoelectronic component according to claim 13, wherein the optoelectronic component is configured to emit white light.
